(19) United States
(12) Patent Application Publication
(10) Pub. No.: US 2026/0070452 A1
(43) Pub. Date: Mar. 12, 2026

(54) BATTERY PROFILING SYSTEM INTEGRATED IN A POWER DISPENSER

(71) Applicant: NANYANG TECHNOLOGICAL UNIVERSITY, Singapore (SG)

(72) Inventors: Howe Li YEO, Singapore (SG); Gil Lampong OPINA, JR., Singapore (SG); Anshuman TRIPATHI, Singapore (SG); Feng LENG, Singapore (SG)

(21) Appl. No.: 19/300,386

(22) Filed: Aug. 14, 2025

Related U.S. Application Data
(60) Provisional application No. 63/692,602, filed on Sep. 9, 2024.

(51) Int. Cl. B60L 53/62; G01R 31/3835; G01R 31/389; G01R 31/392

(52) U.S. Cl. CPC B60L 53/62; G01R 31/3835; G01R 31/389; G01R 31/392; B60L 2240/545

(57) ABSTRACT

A power dispenser configured to charge a battery of an electric vehicle, comprises power dispenser circuitry configured to power the battery; a power dispenser controller configured to control the power dispenser circuitry based on a state of the battery; and a battery profiling system configured to determine the state by obtaining battery metrics of the battery, the battery metrics comprising an internal temperature and an equivalent series resistance (ESR); deriving current battery parameters based on the battery metrics, the current battery parameters comprising a current state-of-health (SOH) and a current state-of-charge (SOC); evaluating the current battery parameters against one or more other battery parameters of the battery or one or more reference parameters; determining the state of the battery based on the evaluating, the state being one of a conforming state or an anomalous state; and providing information based on the determined state to the power dispenser controller.

### CROSS REFERENCE TO RELATED APPLICATION

This present application claims priority to and benefits of U.S. Provisional Application No. 63/692,602, filed on Sep. 9, 2024, titled “Advanced Integrated Battery Charger Profiler,” the content of which is hereby incorporated by reference in its entirety.

### TECHNICAL FIELD

This disclosure pertains to a profiler system that profiles a battery or other energy source. Profiling a battery may include evaluating certain battery parameters to generate a state and/or performance attributes of the battery.

### BACKGROUND

Electric vehicles (EVs) are being increasingly adopted due to initiatives to decarbonize transportation. Batteries used by the electric vehicles need to be evaluated to ensure ongoing safe operation and to track performance degradation.

### SUMMARY

A claimed solution rooted in computer technology overcomes problems specifically arising in the realm of computer technology. In some embodiments, to identify unsafe and/or inefficient operations, a battery profiler system integrated within a power dispenser evaluates battery parameters while the vehicle is connected to the power dispenser to determine a state and/or one or more performance attributes of the battery. Although embodiments herein are being described with regard to battery-type energy sources, embodiments herein may be implemented to characterize other types of energy sources, such as capacitors.

In some embodiments, the battery profiling system may be integrated within a power dispenser configured to power vehicle batteries or other energy sources. While the vehicle is connected to the power dispenser, the battery profiling system can noninvasively evaluate battery parameters to determine the state of a battery in the vehicle. Profiling the battery may include evaluating whether the battery is in a conforming or anomalous state. An anomalous state may indicate that the battery may have tampered with. A conforming state may indicate that the battery appears not to have been tampered with.

In some embodiments, to determine whether the battery is in a conforming or anomalous state, the battery profiling system evaluates one or more particular battery parameters against one or more other battery parameters captured at that time. In some embodiments, the battery profiling system evaluates one or more particular battery parameters against one or more historical battery parameters captured at an earlier time. Notably, the historical battery parameters need not be the same parameters.

In some embodiments, the battery profiling system evaluates one or more particular battery parameters against reference parameters. The reference parameters may include or be based on different battery parameters generated from different batteries. The reference battery parameters may include different historical battery parameters of the different batteries. The reference parameters may correspond to conforming (normal or expected) battery behavior. The reference parameters may correspond to non-conforming (abnormal or unexpected) battery behavior. In some embodiments, the reference parameters may correspond to a common battery type or a common battery category.

Battery parameters may include state-of-health (SOH). For example, the battery profiling system may compare a current SOH and a previously generated SOH of the battery. Because SOH of a battery is expected to decrease over time, were the battery profiling system to detect an increase in the SOH of the battery, then the battery profiling system may determine the battery as being in an anomalous state. A SOH and other battery parameters may be derived from battery metrics. The battery metrics may include electric, thermal, or mechanical battery properties. Examples of battery metrics may include an internal voltage, a terminal voltage across battery terminals, an electric current, a temperature and an equivalent series resistance of the battery.

Battery parameters may include state-of-charge (SOC) relative to an SOH. For example, the battery profiling system may determine a “transitional” SOC when the battery is transitioning between a constant current phase and a constant voltage phase during charging.

The battery profiling system may compare the transitional SOC with a range of expected values of the transitional SOC associated with its corresponding SOH. If the transitional SOC associated with its corresponding SOH deviates from the expected values, e.g., deviates by a threshold amount or percentage, the battery profiling system may determine the battery as being in an anomalous state.

When the battery profiling system determines that the battery is in a conforming state, then the battery profiling system may determine performance attributes, e.g., the remaining useful life, of the battery.

The battery profiling system generates the battery state noninvasively, without having to disassemble the battery or compromise battery functionality. The battery profiling system may be integrated within the power dispenser, thereby enabling the battery profiling system to evaluate the battery before or while it is being charged. Identifying batteries in an anomalous state can prevent damage and/or human injury. For example, if the battery is identified as being in an anomalous state, the power dispenser may terminate power distribution or reduce the amount or rate of power being distributed.

Such monitoring ensures notification of any unlicensed, unsafe, or unknown battery alterations, or performance degradation.

In accordance with some embodiments, the present invention provides a power dispenser configured to charge a battery of an electric vehicle, the power dispenser comprising power dispenser circuitry configured to power a battery of an electric vehicle; a power dispenser controller configured to control the power dispenser circuitry based on a state of the battery; and a battery profiling system configured to determine the state of the battery by obtaining battery metrics of the battery, the battery metrics comprising an internal temperature and an equivalent series resistance (ESR); deriving current battery parameters of the battery based on the battery metrics, the current battery parameters comprising a current state-of-health (SOH) and a current state-of-charge (SOC); evaluating the current battery parameters against one or more other battery parameters of the battery or one or more reference parameters; determining the state of the battery based on the evaluating, the state being one of a conforming state or an anomalous state; and providing information based on the determined state to the power dispenser controller.

In accordance with some embodiments, the present invention provides a method implemented by a power dispenser configured to charge a battery of an electric vehicle, the power dispenser comprising power dispenser circuitry configured to power the battery of the electric vehicle, a power dispenser controller configured to control the power dispenser circuitry based on a state of the battery, and a battery profiling system configured to determine the state of the battery, the method comprising obtaining battery metrics of the battery, the battery metrics comprising an internal temperature and an equivalent series resistance (ESR); deriving current battery parameters of the battery based on the battery metrics, the current battery parameters comprising a current state-of-health (SOH) and a current state-of-charge (SOC); evaluating the current battery parameters against one or more other battery parameters of the battery or one or more reference parameters; determining the state of the battery based on the evaluating, the state being one of a conforming state or an anomalous state; and providing information based on the determined state to the power dispenser controller.

With regard to either the system or the method, in some embodiments, the determining may comprise in response to determining the battery as being in a conforming state, determining a performance attribute of the battery. The performance attribute may comprise remaining useful life (RUL). The one or more other battery parameters may comprise one or more historical battery parameters of the battery. The current battery parameters and the one or more other battery parameters may include a common battery attribute. The evaluating the current battery parameters may comprise comparing the current SOH against a historical SOH. The determining the state may comprise determining the state of the battery as being in an anomalous state in response to determining that the current SOH exceeds the historical SOH. The evaluating the current battery parameters may comprise determining whether the current SOH is less than or equal to the historical SOH; and determining the current SOC by obtaining a transitional SOC of the battery when the battery is transitioning between a constant current (CC) phase and a constant voltage (CV) phase during charging of the battery; and evaluating the transitional SOC against a reference transitional SOC range corresponding to the current SOH. The determining the state may include determining the state of the battery as being in the anomalous state when the transitional SOC is outside of the reference transitional SOC range; and determining the state of the battery as being in the conforming state when the transitional SOC is within the reference transitional SOC range. The power dispenser controller may be configured to modify one or more power dispensing attributes of the power dispenser circuitry in response to the battery being in the anomalous state. The deriving the battery parameters may comprise deriving the SOH based on the internal temperature and the ESR and based on a reference SOH derived from a reference internal temperature and a reference ESR of one or more different batteries. The obtaining the metrics may comprise obtaining the ESR based on a difference between an unperturbed terminal voltage across terminals of the battery and a perturbed terminal voltage across the terminals, the perturbed terminal voltage being obtained when a perturbing current is applied across the terminals.

These and other features of the systems, methods, and non-transitory computer readable media disclosed herein, as well as the methods of operation and functions of the related elements of structure and the combination of parts and economies of manufacture, will become more apparent upon consideration of the following description and the appended claims by referring to the accompanying drawings, all of which form a part of this specification, wherein like reference numerals designate corresponding parts in the various figures. It is to be expressly understood, however, that the drawings are for purposes of illustration and description only and are not intended as a definition of the limits of the invention.

### BRIEF DESCRIPTION OF THE DRAWINGS

FIG. 1A is a diagram of an example battery profiling network, which includes a battery profiling system integrated in a power dispenser for profiling a battery within a vehicle, according to some embodiments of the present invention.

FIG. 1B is a diagram of an example battery, according to some embodiments of the present invention.

FIG. 1C is a diagram of an example user interface of a power dispenser, according to some embodiments of the present invention.

FIG. 2 is a block diagram illustrating details of a battery profiling system, which generates a state of the battery and one or more battery performance attributes, according to some embodiments of the present invention.

FIG. 3A is a flowchart of an example SOH-based battery state determining method, according to some embodiments of the present invention.

FIG. 3B is a flowchart of an example SOC-based battery state determining method, according to some embodiments of the present invention.

FIG. 4 is a diagram that illustrates constant current (CC)/constant voltage (CV) charging phases of a battery, according to some embodiments of the present invention.

FIG. 5 is a diagram that illustrates CC/CV charging phases for different aged batteries, according to some embodiments of the present invention.

FIG. 6A is a diagram that illustrates example reference parameter relationship data, specifically between Equivalent Series Resistance (ESR) and State of Health (SOH), according to some embodiments of the present invention.

FIG. 6B is a diagram that illustrates example reference parameter relationship data, specifically between transitional State of Charge (SOC) and SOH, according to some other embodiments of the present invention.

FIG. 7 is a diagram that illustrates example reference parameter relationship data, specifically between ESR and temperature, according to some other embodiments of the present invention.

### DETAILED DESCRIPTION

A claimed solution rooted in computer technology overcomes problems specifically arising in the realm of computer technology. In some embodiments, to identify unsafe and/or inefficient operations, a battery profiler system integrated within a power dispenser evaluates battery parameters while the vehicle is connected to the power dispenser to determine a state and/or one or more performance attributes of the battery. Although embodiments herein are being described with regard to battery-type energy sources, embodiments herein may be implemented to profile other types of energy sources, such as capacitors.

In some embodiments, the battery profiling system may be integrated within a power dispenser configured to power vehicle batteries or other energy sources. While the vehicle is connected to the power dispenser, the battery profiling system can noninvasively evaluate battery parameters to determine the state of a battery in the vehicle. Profiling the battery may include evaluating whether the battery is in a conforming or anomalous state. An anomalous state may indicate that the battery may have tampered with. A conforming state may indicate that the battery appears not to have been tampered with.

In some embodiments, to determine whether the battery is in a conforming or anomalous state, the battery profiling system evaluates one or more current battery parameters against one or more other battery parameters captured at that time. In some embodiments, the battery profiling system evaluates one or more current battery parameters against one or more historical battery parameters captured at an earlier time. Notably, the historical battery parameters need not be the same parameters.

In some embodiments, the battery profiling system evaluates one or more current battery parameters against reference parameters. The reference parameters may include or be based on different battery parameters generated from different batteries. The reference battery parameters may include different historical battery parameters of the different batteries. The reference parameters may correspond to conforming (normal or expected) battery behavior. The reference parameters may correspond to non-conforming (abnormal or unexpected) battery behavior. In some embodiments, the reference parameters may correspond to a common battery type or a common battery category.

Battery parameters may include state-of-health (SOH). For example, the battery profiling system may compare a current SOH and a historical SOH of the battery. Because SOH of a battery is expected to decrease over time, were the battery profiling system to detect an increase in the SOH of the battery, then the battery profiling system may determine the battery as being in an anomalous state. A SOH and other battery parameters may be derived from battery metrics. The battery metrics may include electric, thermal, or mechanical battery properties. Examples of battery metrics may include an internal voltage, a terminal voltage across battery terminals, an electric current, a temperature and an equivalent series resistance of the battery.

Battery parameters may include state-of-charge (SOC) relative to an SOH. For example, the battery profiling system may determine a “transitional” SOC when the battery is transitioning between a constant current phase and a constant voltage phase during charging.

The battery profiling system may compare the transitional SOC with a range of expected values of the transitional SOC associated with its corresponding SOH. If the transitional SOC associated with its corresponding SOH deviates from the expected values, e.g., deviates by a threshold amount or percentage, the battery profiling system may determine the battery as being in an anomalous state. Else, it may determine the battery as being in a conforming state.

When the battery profiling system determines that the battery is in a conforming state, then the battery profiling system may determine one or more performance attributes, e.g., the remaining useful life, of the battery.

The battery profiling system generates the battery state noninvasively, without having to disassemble the battery or compromise battery functionality. The battery profiling system may be integrated within the power dispenser, thereby enabling the battery profiling system to evaluate the battery before or while it is being charged. Identifying batteries in an anomalous state can prevent damage and/or human injury. For example, if the battery is identified as being in an anomalous state, the power dispenser may terminate power distribution or reduce the amount or rate of power being distributed.

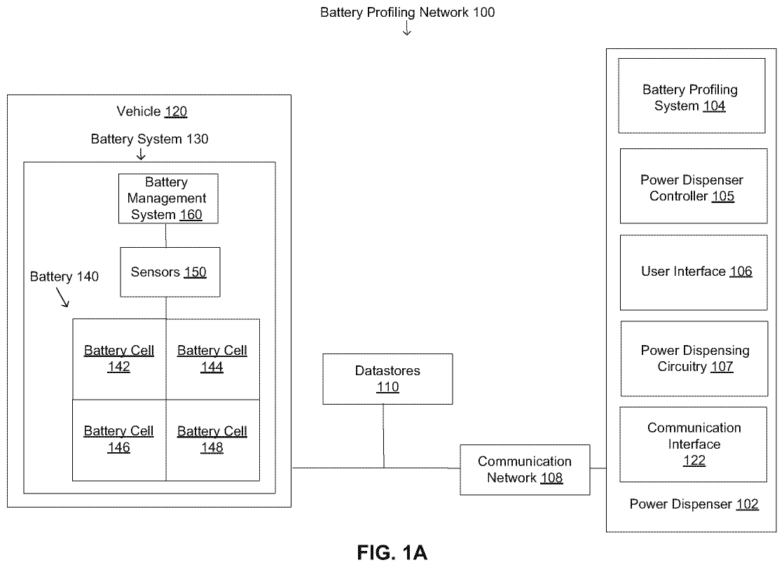

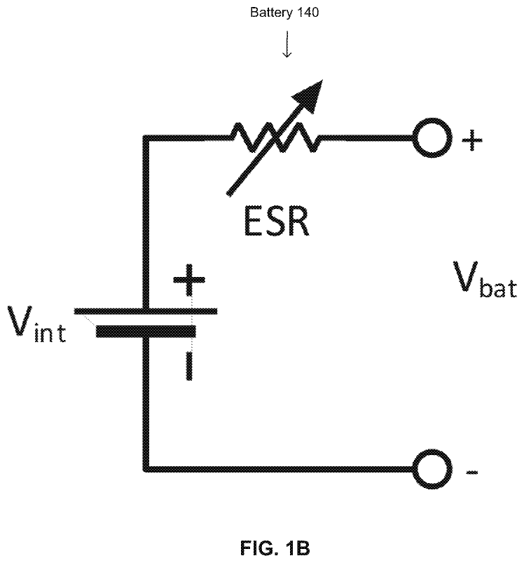

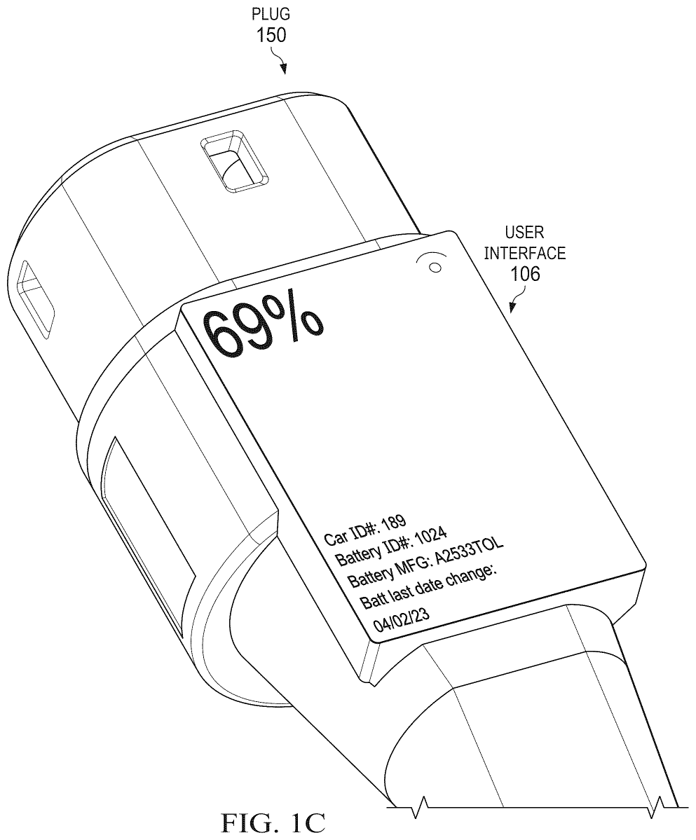

FIG. 1A is a diagram of a battery profiling network 100, which includes a battery profiling system 104 integrated within a power dispenser 102, an electric vehicle 120 that includes a battery system 130 coupled to the power dispenser 102, a communication network 108 and datastores 110. The battery profiling system 104 may determine a state of the battery system 130 or of any individual battery or battery cells within the battery system 130. Profiling may occur while the vehicle 120, or the battery system 130, is connected to the power dispenser 102. Although the description refers to batteries, the implementations described may also be applicable to other energy sources or loads such as supercapacitors.

The battery system 130 includes a battery 140 that supplies input electric power to the vehicle 120. In some embodiments, the battery 140 includes a lithium ion battery, a lead acid battery, or any applicable battery, such as those suitable for vehicles. In some embodiments, the battery 140 includes one or more battery cells, e.g., four battery cells 142, 144, 146, and 148. The battery 140 may include any number of battery cells. Additionally or alternatively, the battery 140 may contain other configurations such as battery modules or battery packs. The battery system 130 may include multiple batteries.

Within the battery system 130, one or more sensors 150 may measure sensor data indicative of one or more battery metrics of the battery 140. The battery metrics may include electric, thermal, or mechanical properties. Examples of battery metrics may include an electric current, an internal voltage, a terminal voltage across battery terminals, a resistance such as an equivalent series resistance, or an internal temperature of the battery 140. In some embodiments, the one or more sensors 150 may obtain electric signals which may be used to derive battery metrics.

The battery system 130 may also contain a battery management system 160 which may monitor the battery metrics and regulate charging and discharging of the battery 140. In some embodiments, the battery management system 160 may perform actions such as shutting down or limiting operations of the battery 140 if certain trigger conditions occur. These trigger conditions may include battery conditions such as over-voltage, over-current, over-temperature, or low voltage conditions.

The power dispenser 102 may be configured to power the battery system 130. The power dispenser 102 may include a power dispensing circuitry 107 and a power dispenser controller 105 configured to control the power dispensing circuitry 107. In some embodiments, the power dispenser controller 105 may control whether the power dispensing circuitry 107 is actively distributing power, and may control power dispensing attributes such as a rate, total amount, or a duration of energy distribution, current transforming attributes of transforming alternating current (AC) to direct current (DC), and any voltage transforming attributes. In some embodiments, the power dispenser controller 105 may control power dispensing attributes based on load balancing considerations, such as amount of energy requested from vehicles, power dispensing attributes at other power dispensing stations, or grid attributes. In some embodiments, the power dispenser controller 105 controls the power dispensing circuitry 107 via control signals that selectively activate or deactivate certain paths of the power dispenser circuitry 107.

The power dispenser circuitry 107 may be configured to receive energy, transform the energy, and distribute the energy to the battery system 130. The power dispenser circuitry 107 may receive energy from different sources such as the grid. Transforming the energy may include transforming current from AC to DC of the received energy, or adjusting a voltage of the received energy prior to distributing the energy. In some embodiments, the power dispenser circuitry 107 may contain solid state transformers (SSTs) which may be equipped to perform bidirectional energy distribution. In some embodiments, the power dispenser circuitry 107 includes one or more harmonic filtering components, other regulating components to counteract voltage sags or swells, and one or more fault detecting components such as circuit breakers. The fault detecting components may, upon detecting a fault in the power dispenser 102, effect shut down of the power dispenser 102.

Within the power dispenser 102, the battery profiling system 104 may include software, hardware, firmware and/or circuits (e.g., collectively referred to as battery profiling circuitry) to determine a state and one or more performance attributes of the battery 140. Here, although only a single battery is illustrated for simplicity, it is understood that the battery system 130 may have any number of batteries and that the battery profiling system 104 may determine the state and performance attribute of each battery or the combination of multiple batteries in the battery system 130. The state of the battery 140 may include whether the battery 140 is in an anomalous state, which may depend upon battery parameters such as a state-of-health (SOH) and a state-of-charge (SOC) of the battery 140. In some embodiments, a SOH may be a ratio of maximum possible energy storable in the battery 140 (e.g., accounting for battery degradation) to a rated energy amount. For a brand new battery, the SOH is expected to be 1 or 100%. The SOH is expected to degrade over time. In some embodiments, a SOC may be a ratio of available energy in the battery 140 to the maximum possible energy storable in the battery 140. Because the maximum possible energy storable decreases over time due to degradation, a same amount of available energy may correspond to a different SOC at different times. Meanwhile, the performance attribute of the battery may include a remaining useful life of the battery 140.

In some embodiments, the battery profiling system 104 may include circuitry that obtains battery metrics, derives or deduces the current battery parameters based on the battery metrics, and determines a state of the battery 140 based on the battery parameters. In some embodiments, determining the state of the battery 140 may be based on an evaluation of the current battery parameters against one or more other battery parameters of the battery, one or more reference parameters, or reference parameter relationship data. In some embodiments, the one or more other battery parameters may correspond to different battery attributes of the battery (e.g., SOH vs. SOC) captured at a same time or a different time as the current battery parameter. Battery attributes may include battery parameters, battery metrics, or other metered or determined properties of the battery 140. In some embodiments, the one or more other battery parameters may correspond to same battery attributes of the battery (e.g., SOH) captured at a different time, such as a previously recorded time, compared to the battery parameter. The reference parameters may include or be based on different battery parameters corresponding to the same battery attribute from different batteries. The different battery parameters may include different historical battery parameters of the different batteries. In some embodiments, the reference parameters may correspond to conforming battery behavior. For example, reference parameters may identify one or more, or a range of, expected or mapped values of the battery parameter, assuming values of one or more other battery parameters or battery metrics. In some embodiments, the reference parameters which the battery parameters are being evaluated against may correspond to a common battery type or a common battery category. Reference parameter relationship data may include relationships of the reference parameters with other reference parameters or reference metrics.

The battery profiling system 104 may determine the state based on a comparison between a present SOH with a previously recorded SOH. If the present SOH is higher than a previously recorded SOH, then the battery profiling system 104 may determine the battery 140 as being in an anomalous state.

The battery profiling system 104 may also determine the state of the battery 140 based on a comparison between a SOC, such as a transitional SOC, with a range of expected values of the transitional SOC at a given SOH (e.g., at the present SOH). The transitional SOC may correspond to a constant current (CC)/constant voltage (CV) transition, at which the battery 140 changes charging phase from a constant current charging phase to a constant voltage charging phase. If the transitional SOC falls outside the range of expected values at the given SOH, then the battery profiling system 104 may determine the battery 140 as being in an anomalous state.

In some embodiments, the battery profiling system 104 may include one or more processors that read and/or write instructions (e.g., which may include expressions, protocols, evaluations, conditions, arguments, and/or functions) to implement control of the operations. These operations may include receiving or transmitting communications from the vehicle 120, the battery system 130, from other power dispensing stations or from other sites on the grid, via one or more communication interfaces 122 which transmit communications to and from the power dispenser 102 via a communication network 108. In some embodiments, the communication interfaces 122 may be configured to convert commands from the power dispenser 102 or the battery profiling system 104 into specific actions. For example, the battery profiling system 104 may generate commands to request battery metrics or battery contextual information from the battery system 130. In some embodiments, the battery contextual information may include any of previously recorded battery metrics, previously recorded battery parameters, battery identification information, or vehicle identification information of the vehicle 120 in which the battery system 130 is housed. Some non-limiting examples of battery contextual information may include a serial number or other identifier of the battery system 130 or of the vehicle 120, a date of one or more previous battery changes, a date of a previous charging session of the battery system 130 or of the vehicle 120, and a SOH of the previous charging session. The communication interfaces 122 may translate commands from the battery profiling system 104. The communication interfaces 122 may direct the translated commands to a proper destination, such as to the battery system 130 to obtain the battery metrics or the battery contextual information. The communication interfaces 122 may be configured for two-way communication, including receiving any communications from the battery system 130, from the vehicle 120, from other power dispenser stations, or from other locations on the grid. As another example, the battery profiling system 104 may generate commands to request reference parameters or reference parameter relationship data, such as ranges of expected values of a transitional SOC for given SOH values. These reference parameters may be stored in one or more datastores 110 which may be implemented within physical or cloud-based servers. The one or more communication interfaces 122 may translate these commands and direct these commands to the datastores 110, retrieve the relevant reference parameters, and communicate the reference parameters to the battery profiling system 104. In some embodiments, the one or more communication interfaces 122 may automatically transmit communications to the battery profiling system 104, the power dispensing circuitry 107, or one or more other power dispenser stations, other locations on the grid, the battery system 130 or the vehicle 120. In some embodiments, the transmission of communications may be performed without a specific command from the power dispenser 102. These communications may be from the vehicle 120, the battery system 130, from other power dispenser stations, other power dispensers or from other sites on the grid.

In some embodiments, the communication interfaces 122 may be configured via control signals and/or user interfaces as needed. In some embodiments, the communication interfaces 122 may communicate with a single interface or any number of interfaces. In some embodiments, the power dispenser 102 may or may not contain the communication interfaces 122. In some embodiments, the battery profiling system 104 and any or all of the interfaces that the battery profiling system 104 communicates with may be combined together to form a battery profiling controller system.

The communication network 108 may include any secured communication network such as an encrypted network. The communication network 108 may represent one or more computer networks (e.g., LAN, WAN, or the like) or other transmission mediums. The communication network 108 may provide communication within the battery profiling network 100 and/or between the battery profiling network 100 and other external systems or networks. In some embodiments, the communication network 108 includes one or more computing devices, routers, cables, buses, and/or other network topologies (e.g., mesh, and the like). In some embodiments, the communication network 108 may be wired and/or wireless. In various embodiments, the communication network 108 may include the Internet, one or more wide area networks (WANs) or local area networks (LANs), one or more networks that may be public, private, IP-based, non-IP based, and so forth.

The power dispenser 102 may include one or more user interfaces 106 that obtain one or more power dispensing commands, such as commencing or terminating a power dispensing session, or one or more requested power dispensing attributes of the power dispensing session. In some embodiments, the user interfaces 106 may include human machine interfaces (HMIs). The obtained power dispensing commands may be communicated to the power dispenser controller 105. In some embodiments, the one or more user interfaces 106 may present power dispensing states, the requested power dispensing attributes, or actual power dispensing attributes. Power dispensing states may include whether a power dispensing session is active or inactive, a power dispensing progress of the power dispensing session such as amount of power dispensed during the power dispensing session or a total elapsed time of the power dispensing session. In some embodiments, the one or more user interfaces 106 may present any of the battery metrics, the battery parameters, or the battery contextual information, as will be illustrated in FIG. 1C.

FIG. 1B is a diagram of an example representation of the battery 140 to illustrate further context regarding the battery metrics. In FIG. 1B, the battery 140 is represented by an internal voltage Vᵢₙₜ, an equivalent series resistance (ESR), and a terminal voltage V_{bat} across positive and negative terminals of the battery 140. The internal voltage Vᵢₙₜ may be an electromotive force (EMF), which indicates a theoretical maximum voltage that the battery 140 can provide when no electric current is flowing. In some embodiments, the ESR includes an internal resistance of the battery 140. The internal resistance of the battery 140 may encompass resistances of an interconnect, battery terminals, and resistances (e.g., ionic resistances) of the electrolyte. The ESR may vary according to internal and external conditions of the battery, such as internal battery temperature or external temperature, concentration of electrolyte, and condition of battery electrodes. The terminal voltage V_{bat} may be an actual voltage when the battery 140 is connected to a load and electric current is flowing.

FIG. 1C is a diagram of an example plug 150 of the power dispenser 102 having a user interface 106. In some embodiments, the user interface 106 may present battery contextual information such as identification information of the vehicle 120 in which the battery system 130 is housed, battery identification information, battery manufacturer information, and a most recent date at which the battery 140 was changed. In some embodiments, the user interface 106 may present battery metrics or battery parameters of the battery system 130, such as a present SOC of the battery 140.

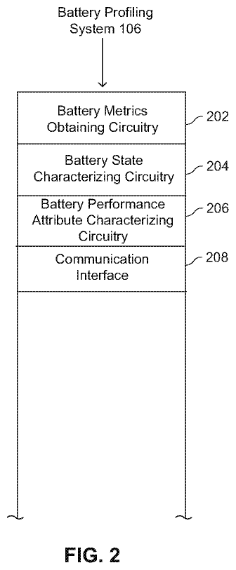

FIG. 2 is a block diagram illustrating details of the battery profiling system 104, which determines a state of the battery and one or more battery performance attributes.

Reference will be made to features in FIGS. 1A and 1B, for additional context. In some embodiments, the battery profiling system 104 includes battery metrics obtaining circuitry 202, battery state characterizing circuitry 204, battery performance attribute characterizing circuitry 206, and one or more communication interfaces 208, which may be implemented as the communication interfaces 122 or the user interfaces 106 previously described in FIG. 1A. Although circuitry is described separately to illustrate different concepts, it is contemplated that the circuitry described separately do not necessarily constitute different or separate circuits. Rather, any of the described circuitry may be integrated or combined into a single circuit.

The battery metrics obtaining circuitry 202 may be configured to obtain one or more battery metrics from the battery system 130. In some embodiments, the battery metrics include electric, thermal, or mechanical battery properties obtained or derived from sensor data acquired from the one or more sensors 150. In some embodiments, the battery metrics may include an internal voltage, a terminal voltage across battery terminals, an internal battery temperature, an electric current, and an ESR of the battery 140. In some embodiments, the battery metrics may be obtained under different perturbing conditions. For example, the terminal voltage across battery terminals may be measured under unperturbed conditions in which no electric current is flowing through the battery 140, to obtain or approximate the internal voltage. This may be referred to as an unperturbed voltage. Additionally, the terminal voltage across battery terminals may be measured under one or more perturbed conditions in which a small amount of perturbing electric current is flowing through the battery 140. This may be referred to as a perturbed voltage.

In some embodiments, the battery metrics obtaining circuitry 202 may derive some of the battery metrics of the battery 140 from other battery metrics of the battery 140. For example, the battery metrics obtaining circuitry 202 may obtain the ESR of the battery 140 by taking a difference between the perturbed voltage and the unperturbed voltage, and dividing the difference by the amount of the perturbing electric current.

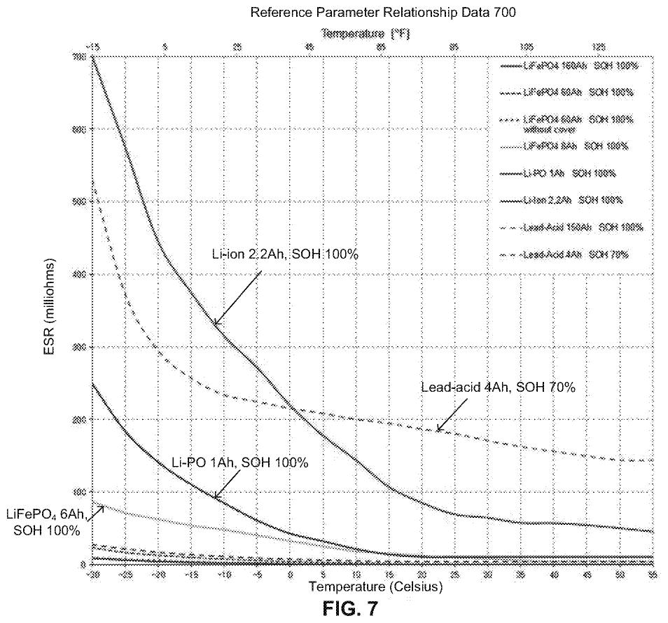

The battery state characterizing circuitry 204 may be configured to determine a state of the battery 140. In some embodiments, a state may refer to whether the battery 140 is in an anomalous state, which may indicate potential tampering of the battery 140, or a conforming state, which may indicate a likelihood of no tampering of the battery 140. In some embodiments, the battery state characterizing circuitry 204 may determine the state of the battery 140 based on one or more battery parameters such as the SOH and the SOC. In some embodiments, the battery state characterizing circuitry 204 may derive the battery parameters from the battery metrics of the battery 140 or from other battery parameters of the battery 140. For example, the SOH may be derived based on the ESR and the internal battery temperature of the battery 140. In some embodiments, deriving the SOH may be based on one or more reference parameters or reference parameter relationship data. For example, the SOH may be derived based on reference SOH values mapped to a combination of reference ESR values and reference internal temperatures, as illustrated in FIG. 7. In some embodiments, the reference SOH values may correspond to specific reference battery types. In some embodiments, the battery state characterizing circuitry 204 may derive or obtain the battery parameters based on a charging behavior of the battery 140. For example, the battery state characterizing circuitry 204 may obtain a transitional SOC during a CC/CV transition, during which the battery 140 changes from a CC charging phase to a CV charging phase.

In some embodiments, the battery state characterizing circuitry 204 may be configured to determine a state of the battery 140 based on an evaluation of the current battery parameters against one or more other battery parameters of the battery, one or more reference parameters, or reference parameter relationship data. For example, the battery state characterizing circuitry 204 may compare a battery parameter such as a SOH to one or more historical SOH values of the battery 140. If the battery state characterizing circuitry 204 determines that the SOH is higher than one or more historical SOH values, the battery state characterizing circuitry 204 may determine the battery 140 as being in an anomalous state. As another example, the battery state characterizing circuitry 204 may compare a battery parameter such as a transitional SOC to reference parameters such as reference transitional SOC values, which indicates one or more ranges of expected values of the transitional SOC assuming a given SOH. If the transitional SOC falls outside of the ranges of expected values, the battery state characterizing circuitry 204 may determine the battery 140 as being in an anomalous state. Similarly, the battery state characterizing circuitry 204 may determine a state of the battery 140 based on detecting whether an inconsistency exists, or a likelihood of an inconsistency exists between battery parameters. For example, the battery state characterizing circuitry 204 may detect an inconsistency between the transitional SOC and the SOH of the battery 140. Such an inconsistency may exist if, given a value of the transitional SOC, the present SOH falls outside of expected values of the SOH, and vice versa.

The battery state characterizing circuitry 204 may output an indication of the determined state. For example, the battery state characterizing circuitry 204 may output a warning or other indication upon determining the battery as being in an anomalous state. In some embodiments, the battery state characterizing circuitry 204 may cause the power dispenser 102 to modify power distribution attributes, such as terminating a power distribution session or slowing down the power distribution process. The battery state characterizing circuitry 204 may communicate the anomalous state to the power dispenser controller 105 to cause modification of power distribution attributes.

The battery performance attribute characterizing circuitry 206 may be configured to determine a performance attribute of the battery 140. In some embodiments, determining of the performance attribute may be in response to the battery state characterizing circuitry 204 determining the battery as being in a conforming state. In some embodiments, the performance attribute may include a remaining useful life of the battery 140. The battery performance attribute characterizing circuitry 206 may determine or estimate the remaining useful life based on the present SOH and based on a previously recorded SOH. In some embodiments, the battery performance attribute characterizing circuitry 206 may determine or estimate the remaining useful life based on a rate of deterioration of the SOH. For example, the determination or estimation of the remaining useful life may be based on a transformation, such as a linear interpolation, between a most recent previously recorded SOH and the present SOH. In some embodiments, one or more machine learning algorithms may additionally or alternatively be implemented to determine the remaining useful life.

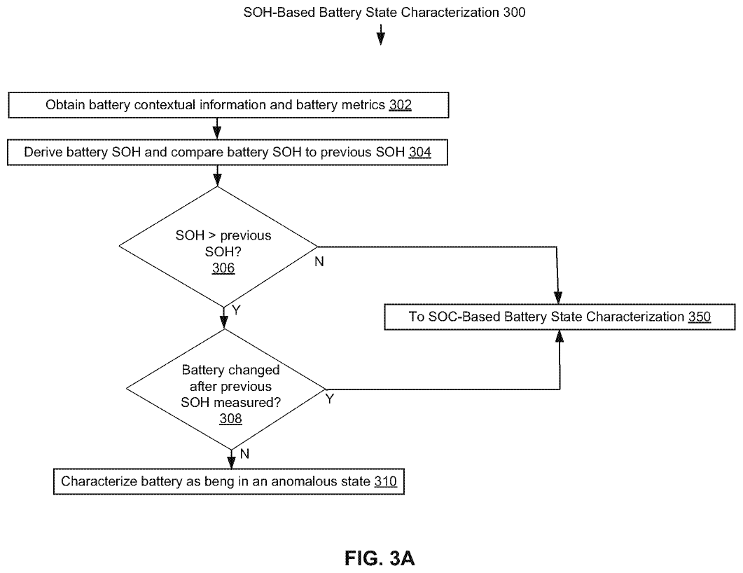

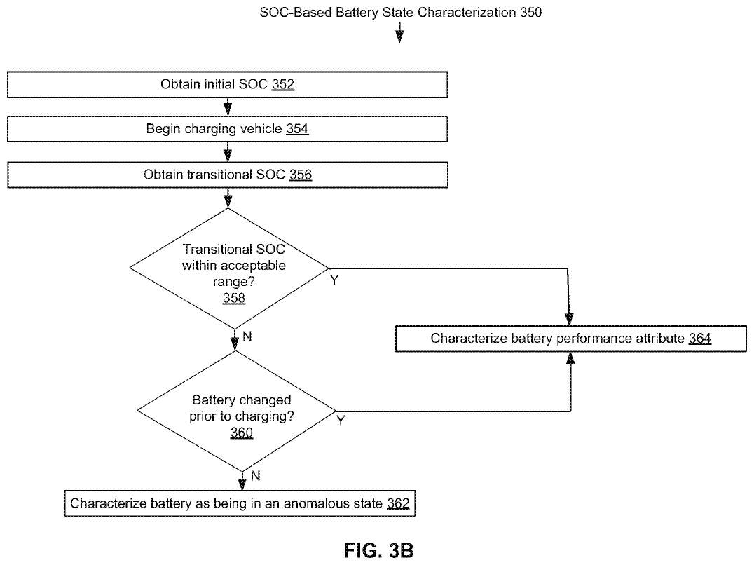

FIG. 3A is a flowchart of a SOH-based battery state characterization method 300, as implemented within the power dispenser 102. In this and other flowcharts and/or sequence diagrams, the flowchart illustrates by way of example a sequence of steps. It should be understood the steps may be reorganized for parallel execution, or reordered, as applicable. Moreover, some steps that could have been included may have been removed to avoid providing too much information for the sake of clarity and some steps that were included could be removed, but may have been included for the sake of illustrative clarity.

SOH-based battery state characterization method 300 begins with step 302, in which the battery profiling system 104 (e.g., the battery metrics obtaining circuitry 202) obtains battery contextual information and battery metrics of the battery 140. In some embodiments, the battery contextual information, as described in FIG. 1A, may include any of historical battery metrics, historical battery parameters (e.g., a previously recorded SOH), battery identification information, or vehicle identification information of the vehicle 120 in which the battery system 130 is housed. In some embodiments, the battery metrics, as described in FIG. 1A, may include any of an internal voltage, a terminal voltage across battery terminals, an electric current, a temperature and an ESR of the battery. In step 304, the battery profiling system 104 (e.g., the battery state characterizing circuitry 204) obtains or derives battery parameters such as the battery SOH. In some embodiments, the battery SOH may be derived based on the internal temperature of the battery 140 and the ESR of the battery 140.

The battery state characterizing circuitry 204 may derive the battery SOH based on a lookup table. Additionally or alternatively, the battery state characterizing circuitry 204 may derive the battery SOH based on reference parameters or reference parameter relationship data, such as a reference SOH that is most closely mapped to the internal temperature and the ESR, which is further illustrated in FIG. 7.

In decision 306, the battery state characterizing circuitry 204 may determine whether the battery SOH, derived in step 304, is greater than a historical SOH. If so, the battery state characterizing circuitry 204 may determine whether the battery has been changed after measuring or recording the previously recorded SOH (e.g., prior to the determination of the SOH in step 304). This corresponds to decision 308. Upon a positive determination in decision 308, the SOH-based battery state characterization method 300 may proceed to a SOC-based battery state characterization method 350, as illustrated in FIG. 3B. A positive determination in decision 308 signifies that whether or not the battery 140 is in an anomalous state is inconclusive, using SOH-based battery characterization. Upon a negative determination in decision 308, the battery state characterizing circuitry 204 may determine the battery 140 as being in an anomalous state in step 310, because a battery SOH cannot increase over time through normal battery operation.

FIG. 3B is a flowchart of a SOC-based battery state characterization method 350, as implemented within the power dispenser 102. SOC-based battery state characterization method 350 begins with step 352, in which the battery profiling system 104 (e.g., the battery state characterizing circuitry 204) obtains an initial SOC of the battery 140. In some embodiments, the initial SOC may be obtained based on the unperturbed voltage or coulomb counting. In some embodiments, the initial SOC may be obtained, verified, or adjusted using machine learning algorithms. The machine learning algorithms may be stored in cloud-based servers. In some embodiments, one purpose of obtaining an initial SOC is to verify that the initial SOC is below the transitional SOC (e.g., a reference transitional SOC given the SOH determined in step 304), so that the transitional SOC may be obtained during charging.

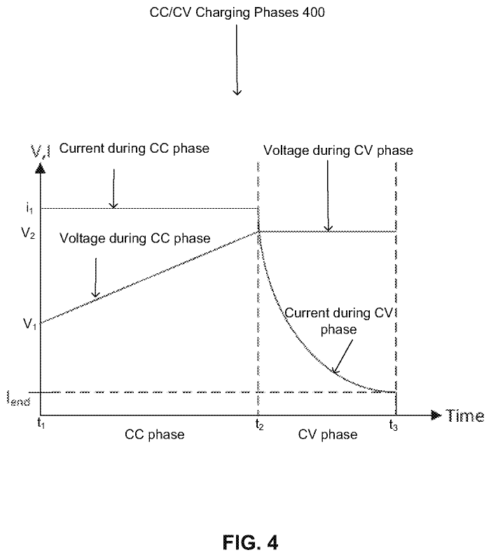

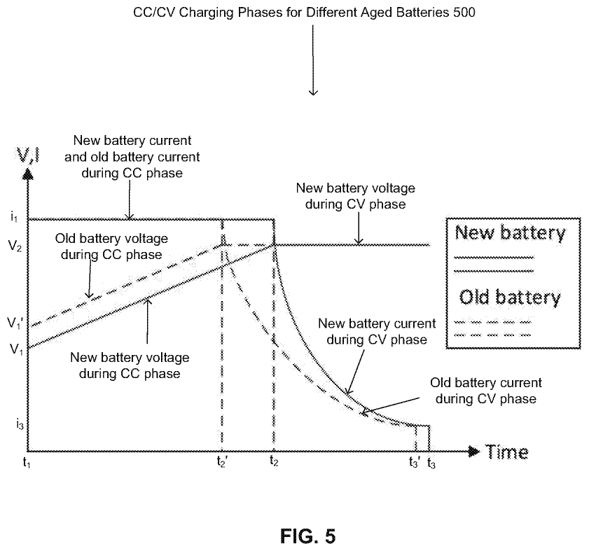

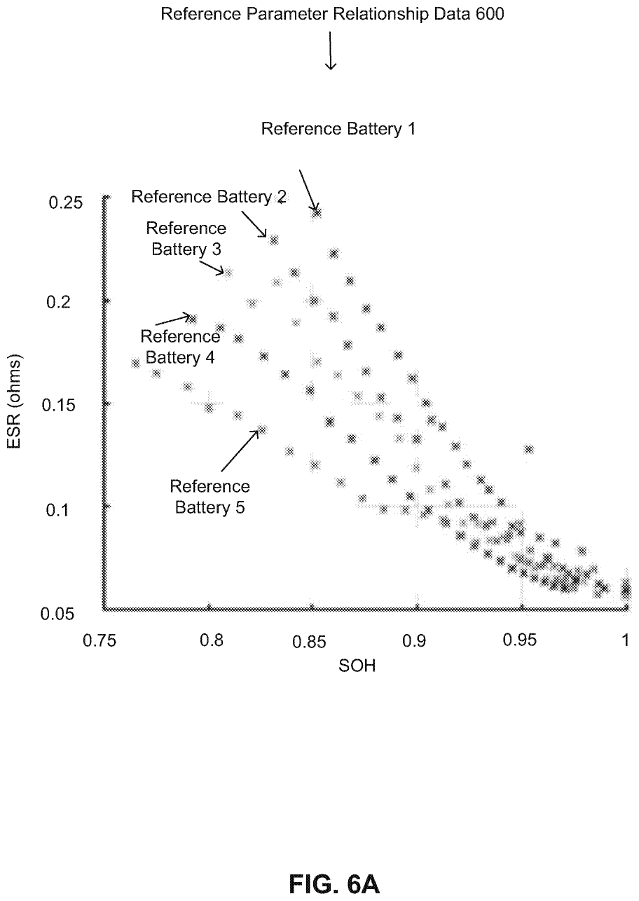

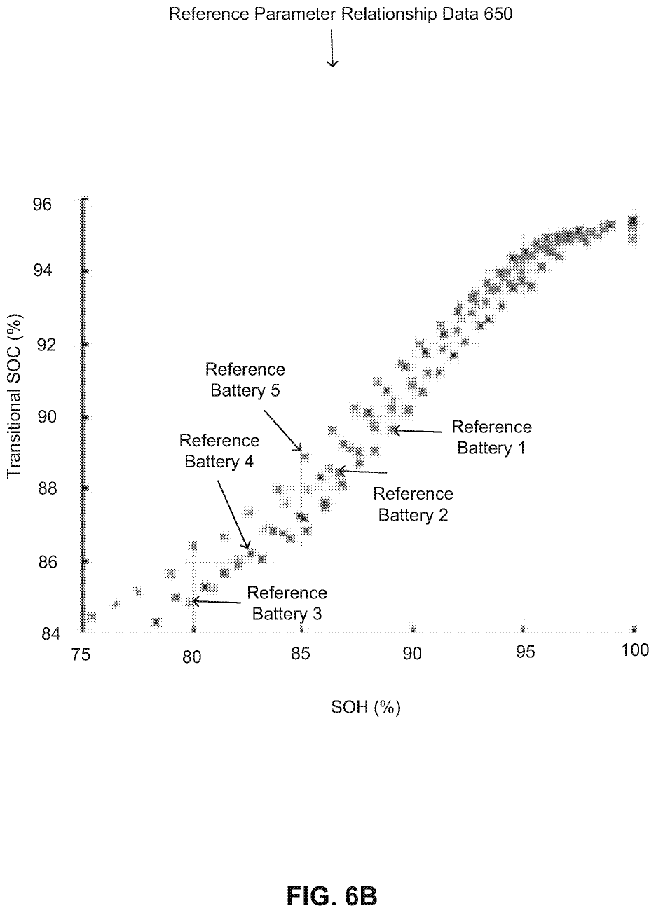

In step 354, the power dispenser 104 begins charging the battery system 130 of the vehicle 120. Charging may include CC/CV charging phases, as illustrated in FIGS. 4 and 5. In step 356, the battery state characterizing circuitry 204 obtains the transitional SOC, in which the battery 140 transitions from a CC charging phase to a CV charging phase. For example, the battery state characterizing circuitry 204 may record a SOC at a precise instance at which the battery 140 transitions from the CC charging phase to the CV charging phase. In decision 358, the battery state characterizing circuitry 204 may determine whether the transitional SOC is within an acceptable range (e.g., a range of expected values). In some embodiments, the acceptable range may be defined based on a reference transitional SOC range, which may be obtained from reference transitional SOCs of one or more different batteries as illustrated in FIGS. 6A and 6B.

Upon a positive determination in decision 358, the battery performance attribute characterizing circuitry 206 may determine a battery performance attribute such as a remaining useful life in step 364. In some embodiments, the remaining useful life may be determined based on the present SOH and based on a previously recorded SOH. In some embodiments, the battery performance attribute characterizing circuitry 206 may determine or estimate the remaining useful life based on a rate of deterioration of the SOH. For example, the determination or estimation of the remaining useful life may be based on a transformation, such as a linear interpolation, between a most recent previously recorded SOH and the present SOH. In some embodiments, one or more machine learning algorithms may additionally or alternatively be implemented to determine the remaining useful life.

Upon a negative determination in decision 358, the battery state characterizing circuitry 204 may determine whether the battery was changed prior to charging, and after the previously recorded SOH (e.g., prior to the determination of the SOH in step 304) in decision 360. Upon a positive determination in decision 360, the battery performance attribute characterizing circuitry 206 may determine a battery performance attribute such as a remaining useful life in step 364. Upon a negative determination in decision 360, the battery state characterizing circuitry 204 may determine the battery 140 as being in an anomalous state in step 362. In some embodiments, in step 362 or in step 310, the battery state characterizing circuitry 204 may determine a level of severity of the anomalous state, which may be based on how far the battery transitional SOC deviates from the expected values in decision 358 or an extent of deviation between the present SOH and a previously recorded SOH in step 304.

In some embodiments, upon determining the battery 140 as being in an anomalous state either in step 362 or in step 310, the battery state characterizing circuitry 204 may output a notification such as an alert regarding the determined anomalous state. For example, the alert may be manifested in textual or pictorial format (e.g., on the user interface 106 or on a dashboard or console of the vehicle 120), or in audio format as outputted from the power dispenser 102. In some embodiments, upon determining the battery 140 as being in an anomalous state, the battery state characterizing circuitry 204 may cause the power dispenser 104 to terminate power distribution or reduce amount or rate of power distributed by communicating the anomalous state or a level of severity of the anomaly to the power dispenser controller. For example, if the battery state characterizing circuitry 204 determines the anomalous state as more severe, the battery state characterizing circuitry 204 may cause more drastic measures to be implemented by the power dispenser 104 such as immediate termination. If the battery state characterizing circuitry 204 determines the anomalous state as less severe, the battery state characterizing circuitry 204 may cause less drastic measures to be implemented by the power dispenser 104 such as slowing down power distribution or delayed termination.

FIG. 4 is a diagram that illustrates CC/CV charging phases 400 of a battery, which provides additional context for FIGS. 1A, 1B, 2, 3A and 3B. In FIG. 4, initially, between times t₁ and t₂, the battery may be in a CC charging phase. During this time window, the battery is in a CC phase, with the current in through the battery being constant and the terminal voltage of the battery is below a threshold voltage V₂. As charging occurs, the terminal voltage of the battery may increase from a voltage V₁ at time t₁, to the threshold voltage V₂ at time t₂. Once the battery reaches the threshold voltage V₂, the battery transitions to a CV phase, which spans a time window from t₂ to t₃. Thus, the transitional SOC, as described previously in FIGS. 1A and 3B, may be obtained at the time t₂. During the CV phase, the voltage remains constant at the threshold voltage V₂ in order to prevent overvoltage. The current may decrease from i₁ at time t₂ to i_{end} at time t₃. i_{end} may correspond to a battery current prior to charging. Charging may be terminated at time t₃.

FIG. 5 is a diagram that illustrates CC/CV charging phases 500 for different aged batteries, which provides additional context for FIGS. 1A, 1B, 2, 3A and 3B. In FIG. 5, initially, between times t₁ and t₂, a new battery may be in a CC charging phase. Between times t₂ and t₃, a new battery may be in a CV charging phase. During the time window from t₁ to t₂, the new battery may have a current in while the voltage increases from V₁ to V₂. During the time window from t₂ to t₃, the new battery may have a voltage V₂ while the current decreases from i₁ to i₃.

For an old battery, a CC charging phase may be between times t₁ and t_{2′} while a CV charging phase may be between times t_{2′} and t_{3′}. During the time window from t₁ to t_{2′} the old battery may have a current in while the voltage increases from V_{1′} to V₂. During the time window from t_{2′} to t_{3′}, the old battery may have a voltage V₂ while the current decreases from in to i₃. For an old battery, the CC/CV transition, at which the transitional SOC may be measured, is at time t2′, which is earlier than the CC/CV transition time t₂ for the new battery. The earlier CC/CV transition is due to a reduction of total energy storable in the old battery, a reduced SOH for the old battery compared to the new battery, and a higher ESR for the old battery.

FIG. 6A is a diagram that illustrates example reference parameter relationship data 600, which may be utilized to derive battery parameters by the battery anomaly detecting circuitry 204, as described in FIGS. 1A, 2, 3A and 3B. FIGS. 6A and 6B illustrate a predetermined or premapped relationship between reference ESRs and reference SOHs of different reference batteries which are distinct from the battery 140. It is understood that in FIGS. 6A and 6B, the relationships depicted are not to be construed as limiting, and are used mainly to illustrate a concept of how such relationships may be leveraged by the battery anomaly detecting circuitry 204 to derive battery parameters. The aforementioned relationship may be used to derive the battery SOH, given the battery ESR. Reference batteries 1 through 5 may include different battery types. For example, if the battery 140 is of a type that matches reference battery 5, then the battery SOH of battery 140 may be derived from the predetermined relationship between the reference ESR and the reference SOH of reference battery 5. Specifically, if battery 140 has a battery ESR of 0.15 ohms, then the battery state characterizing circuitry 204 may derive the SOH as being approximately 0.8 because for reference battery 5, a reference ESR of 0.15 corresponds to a reference SOH of approximately 0.15.

FIG. 6B is a diagram that illustrates example reference parameter relationship data 650, specifically, a predetermined relationship between reference SOHs and reference transitional SOCs of different reference batteries. An expected range of transitional SOCs may be derived from the aforementioned predetermined relationship. For example, the expected range may include any SOC values within a threshold SOC range of a mapped value of a reference SOC given a reference SOH. Specifically, for reference battery 5, and given a reference SOH of 0.8, the mapped value of the reference SOC is approximately 86.3 percent. If the threshold SOC range is 5 percent, then the expected range for a reference SOH of 0.8 would be between 81.3 percent and 91.3 percent. It is understood that the threshold SOC range may be any percentage or value, such as any values between 0.01 percent and 10 percent. The threshold SOC range may depend on factors such as a battery type or the battery SOH.

In some embodiments, multiple reference batteries (e.g., any of reference batteries 1 through 5) may be used to derive an expected range. A weighted average of reference SOCs for a given reference SOH may be obtained across the multiple reference batteries, and an expected value may be derived based on a threshold SOC range centered around the weighted average. The reference batteries that are selected to derive an expected range may be those having sufficient similarly to the battery 140, or that are closest in similarity to the battery 140. To illustrate, assume for the sake of example that reference battery 3 and reference battery 5 are used to derive the expected range. For reference battery 3 and given a reference SOH of 0.8, the mapped value of the reference SOC is approximately 85 percent. Taking an average of the reference SOCs of the reference batteries 3 and 5 at the reference SOH of 0.8 yields 85.65 percent. If the threshold SOC range is 5 percent, then the expected range for a reference SOH of 0.8 would be between 80.65 percent and 90.65 percent. In some embodiments, individual expected ranges for different reference batteries may be derived individually and a union or intersection of the individual expected ranges may be defined as the expected range. For example, the individual expected range for reference battery 3 at the reference SOH of 0.8 would be between 80 percent and 90 percent. Taking a union of the individual expected ranges for reference batteries 3 and 5 would yield an expected range of between 80 percent and 91.3 percent. Taking an intersection of the individual expected ranges for reference batteries 3 and 5 would yield an expected range of between 81.3 percent and 90 percent.

The battery state characterizing circuitry 204 may obtain a transitional SOC of the battery 140 and evaluate the transitional SOC against the expected range from the one or more reference SOCs. If the transitional SOC falls within the expected range, the battery state characterizing circuitry 204 may determine the battery 140 as being in a conforming state. If the transitional SOC falls outside of the expected range, the battery state characterizing circuitry 204 may determine the battery 140 as being in an anomalous state.

FIG. 7 is a diagram that illustrates example reference parameter relationship data 700, which may be utilized to derive battery parameters by the battery anomaly detecting circuitry 204, as described in FIGS. 1A, 2, 3A and 3B. In particular, FIG. 7 illustrates reference curves depicting a predetermined relationship between reference ESRs, reference internal battery temperatures, and reference SOHs of different reference batteries, which may belong to one or more different battery types. It is understood that in FIG. 7, the relationships depicted are not to be construed as limiting, and are used mainly to illustrate a concept of how such relationships may be leveraged by the battery anomaly detecting circuitry 204 to derive battery parameters.

As indicated above, the battery SOH of the battery 140 may be derived from the aforementioned reference parameter relationship data. Deriving the battery SOH may require the battery metrics obtaining circuitry 202 to obtain the battery ESR and the battery internal temperature or a series or range of battery ESRs and battery internal temperatures. It is understood that the principles illustrated in FIG. 6A, 6B, or FIG. 7, or any or all of the figures, may be used to derive the battery SOH. In particular, FIGS. 6A and 6B illustrate deriving the battery SOH based on the battery internal resistance while FIG. 7 illustrates deriving the battery SOH based on the battery ESR and the battery internal temperature.

As an illustrative example, the battery anomaly detecting circuitry 204 may compare one or more battery ESR and battery internal temperature values to the reference curves in FIG. 7. Each of the reference curves corresponds to, or is mapped to, a particular reference SOH. The battery anomaly detecting circuitry 204 may select one or more of the reference curves as sufficiently conforming, or closest conforming, to the one or more battery ESR and battery internal temperature values of the battery 140. The battery anomaly detecting circuitry 204 may derive the battery SOH from one or more reference SOHs mapped to the selected reference curves.

For example, if the battery ESR and the battery internal temperature of the battery 140 are 200 milliohms at 10 degrees Celsius, 190 milliohms at 15 degrees Celsius, and 180 milliohms at 20 degrees Celsius, then the battery anomaly detecting circuitry 204 may select the reference curve corresponding to a SOH of 70 percent as conforming most closely. The battery anomaly detecting circuitry 204 may derive a battery SOH of 70 percent.

It will be appreciated that the term “or,” as used herein, may be construed in either an inclusive or exclusive sense. Moreover, plural instances may be provided for resources, operations, or structures described herein as a single instance. It will be appreciated that the term “request” or “command” shall include any computer or electronic request or instruction, whether permissive or mandatory.

The datastores described herein may be any suitable structure (e.g., an active database, a relational database, a self-referential database, a table, a matrix, an array, a flat file, a documented-oriented storage system, a non-relational No-SQL system, and the like), and may be cloud-based or otherwise.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Any reference to “approximate,” “close,” “near,” a “threshold” or “sufficiency” may be construed to encompass any applicable value or degree, such as any applicable value or degree sufficient to satisfy a given outcome. Recitation of numeric ranges of values throughout the specification is intended to serve as a shorthand notation of referring individually to each separate value falling within the range inclusive of the values defining the range, and each separate value is incorporated in the specification as it were individually recited herein. Any reference to “approximate,” “close,” “near,” a “threshold” or “sufficiency” may be construed to encompass values within a certain range of the specified value, such as within 25 percent, 10 percent, 5 percent, 1 percent, 0.5 percent, 0.25 percent, 0.1 percent, or any other applicable value. In other embodiments, “approximate,” “close,” “near,” a “threshold” or “sufficiency” may refer to a value or entity being within a design tolerance or to achieve an objective or result or to satisfy a given outcome. For example, approximate battery parameters may refer to battery parameter values of SOH or SOC to reliably determine a state of the battery, within a certain probability or confidence level.

The phrases “at least one of,” “at least one selected from the group of,” or “at least one selected from the group consisting of,” and the like are to be interpreted in the disjunctive (e.g., not to be interpreted as at least one of A and at least one of B).

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiment.

Additionally, the singular forms “a,” “an” and “the” include plural referents unless the context clearly dictates otherwise.

The present invention(s) are described above with reference to example embodiments. It will be apparent to those skilled in the art that various modifications may be made and other embodiments may be used without departing from the broader scope of the present invention(s). Therefore, these and other variations upon the example embodiments are intended to be covered by the present invention(s).

1. A power dispenser configured to charge a battery of an electric vehicle, the power dispenser comprising:
power dispenser circuitry configured to power a battery of an electric vehicle;
a power dispenser controller configured to control the power dispenser circuitry based on a state of the battery; and
a battery profiling system configured to determine the state of the battery by
obtaining battery metrics of the battery, the battery metrics comprising an internal temperature and an equivalent series resistance (ESR), the obtaining the battery metrics comprising obtaining the ESR based on a difference between an unperturbed terminal voltage across terminals of the battery and a perturbed terminal voltage across the terminals, the perturbed terminal voltage being obtained when a perturbing current is applied across the terminals;
deriving current battery parameters of the battery based on the battery metrics, the current battery parameters comprising a current state-of-health (SOH) and a current state-of-charge (SOC);
evaluating the current battery parameters against one or more other battery parameters of the battery or one or more reference parameters;
determining the state of the battery based on the evaluating, the state being one of a conforming state or an anomalous state; and
providing information based on the determined state to the power dispenser controller.

2. The power dispenser of claim 1, wherein the determining comprises:
in response to determining the battery as being in a conforming state, determining a performance attribute of the battery.

3. The power dispenser of claim 2, wherein the performance attribute comprises remaining useful life (RUL).

4. The power dispenser of claim 1, wherein the one or more other battery parameters comprise one or more historical battery parameters of the battery.

5. The power dispenser of claim 4, wherein the current battery parameters and the one or more other battery parameters include a common battery attribute.

6. The power dispenser of claim 1, wherein the evaluating the current battery parameters comprises comparing the current SOH against a historical SOH.

7. The power dispenser of claim 6, wherein the determining the state comprises determining the state of the battery as being in an anomalous state in response to determining that the current SOH exceeds the historical SOH.

8. The power dispenser of claim 1, wherein the evaluating the current battery parameters comprises
determining whether the current SOH is less than or equal to the historical SOH; and
determining the current SOC by
obtaining a transitional SOC of the battery when the battery is transitioning between a constant current (CC) phase and a constant voltage (CV) phase during charging of the battery; and
evaluating the transitional SOC against a reference transitional SOC range corresponding to the current SOH.

9. The power dispenser of claim 8, wherein the determining the state includes
determining the state of the battery as being in the anomalous state when the transitional SOC is outside of the reference transitional SOC range; and
determining the state of the battery as being in the conforming state when the transitional SOC is within the reference transitional SOC range.

10. The power dispenser of claim 1, wherein the power dispenser controller is configured to modify one or more power dispensing attributes of the power dispenser circuitry in response to the battery being in the anomalous state.

11. The power dispenser of claim 1, wherein deriving the battery parameters comprises deriving the SOH based on the internal temperature and the ESR and based on a reference SOH derived from a reference internal temperature and a reference ESR of one or more different batteries.

12. (canceled)

13. A method implemented by a power dispenser configured to charge a battery of an electric vehicle, the power dispenser comprising power dispenser circuitry configured to power the battery of the electric vehicle, a power dispenser controller configured to control the power dispenser circuitry based on a state of the battery, and a battery profiling system configured to determine the state of the battery, the method comprising:
obtaining battery metrics of the battery, the battery metrics comprising an internal temperature and an equivalent series resistance (ESR), the obtaining the metrics comprising obtaining the ESR based on a difference between an unperturbed terminal voltage across terminals of the battery and a perturbed terminal voltage across the terminals, the perturbed terminal voltage being obtained when a perturbing current is applied across the terminals;
deriving current battery parameters of the battery based on the battery metrics, the current battery parameters comprising a current state-of-health (SOH) and a current state-of-charge (SOC);
evaluating the current battery parameters against one or more other battery parameters of the battery or one or more reference parameters;
determining the state of the battery based on the evaluating, the state being one of a conforming state or an anomalous state; and
providing information based on the determined state to the power dispenser controller.

14. The method of claim 13, wherein the determining comprises:
in response to determining the battery as being in a conforming state, determining a performance attribute of the battery.

15. The method of claim 14, wherein the performance attribute comprises remaining useful life (RUL).

16. The method of claim 13, wherein the one or more other battery parameters comprise one or more historical battery parameters of the battery.

17. The method of claim 16, wherein the current battery parameters and the one or more other battery parameters include a common battery attribute.

18. The method of claim 13, wherein the evaluating the current battery parameters comprises comparing the current SOH against a historical SOH.

19. The method of claim 18, wherein the determining the state comprises determining the state of the battery as being in an anomalous state in response to determining that the current SOH exceeds the historical SOH.

20. The method of claim 13, wherein the evaluating the current battery parameters comprises
determining whether the current SOH is less than or equal to the historical SOH; and
determining the current SOC by
obtaining a transitional SOC of the battery when the battery is transitioning between a constant current (CC) phase and a constant voltage (CV) phase during charging of the battery; and
evaluating the transitional SOC against a reference transitional SOC range corresponding to the current SOH.

21. The method of claim 20, wherein the determining the state includes determining the state of the battery as being in the anomalous state when the transitional SOC is outside of the reference transitional SOC range; and
determining the state of the battery as being in the conforming state when the transitional SOC is within the reference transitional SOC range.

22. The method of claim 13, wherein the power dispenser controller is configured to modify one or more power dispensing attributes of the power dispenser circuitry in response to the battery being in the anomalous state.

23. The method of claim 13, wherein deriving the battery parameters comprises deriving the SOH based on the internal temperature and the ESR and based on a reference SOH derived from a reference internal temperature and a reference ESR of one or more different batteries.

24. (canceled)
